(19) United States
(12) Patent Application Publication
(10) Pub. No.: US 2010/0200892 A1
(43) Pub. Date: Aug. 12, 2010

(54) TUNNEL DEVICE

(76) Inventors: Yen-Wei Hsu, Taipei (TW); Whie-Chyou Wu, Fremont, CA (US)

Correspondence Address: Yen-Wei Hsu, 7F No. 58, Jhouzih St., Neihu District, TAIPEI, 114, TW

(21) Appl. No.: 12/367,553

(22) Filed: Feb. 9, 2009

(51) Int. Cl. H01L 29/88

(52) U.S. Cl. 257/104; 257/E29.339

(57) ABSTRACT

This invention relates to a tunnel device which can generate tunneling effect with multi-band waveforms. The tunnel device can also be interacted with the field which includes thermal field, optical field, electric field, magnetic field, pressure field, acoustic field, or any combination of them. This tunnel device can be a power conversion device for driving high speed loading such as p-n junction device.

### FIELD OF INVENTION

This invention relates to a tunnel device, and, more particularly, to such a device is field-interacted and can generate tunneling effect with self-excited multi-band waveforms. The tunnel device is interacted with the field which includes thermal field, optical field, electric field, magnetic field, pressure field, acoustic field, or any combination of them. The field-interacted tunnel device is good for driving high speed loading such as p-n junction device.

### BACKGROUND INFORMATION

The background information section includes information related to the present invention and it begins with the definitions of positive and negative differential resistors respectively in short as PDR and NDR. A PDR and NDR coupled in series can function as a damper, which will also be discussed. The impedance of the circuit has been analyzed in the analytic continuation section of the background information.

### INTRODUCTION

Referring to [5], [34], [41, Vol. 1 Chapter 50] and [24, Page 402], the nonlinear system response produces many un-modeled effects: jump or singularity, bifurcation, rectification, harmonic and subharmonic generations, frequency-amplitude relationship, phase-amplitude relationship, frequency entrainment, nonlinear oscillation, stability, modulations(amplitude, frequency, phase) and chaoes. In the nonlinear analysis fields, it needs to develop the mathematical tools for obtaining the resolution of nonlinearity. Up to now, there exists three fundamental problems which are self-adjoint operator, spectral(harmonic) analysis, and scattering problems, referred to [32, Chapter 4.], [38, Page 303], [35, Chapter X], [37, Chapter XI], [36, Chapter XIII], [25] and [34, Chapter 7.].

There are many articles involved the topics of the nonlinear spectral analysis and reviewed as the following sections. The first one is the nonlinear dynamics and self-excited or self-oscillation systems. It provides a profound viewpoint of the non-linear

TABLE 1
Mechanical v.s. Electrical Systems

| Mechanical Systems | | Electrical Systems | |
|---|---|---|---|
| m | mass | L | inductance |
| y | displacement | q | charge |
| $\frac{dy}{dt} = v$ | velocity | $\frac{dq}{dt} = i$ | current |
| c | damping | R | resistance |
| k | spring constant | 1/C | reciprocal of capacitance |
| f (t) | input or driving force | E (t) | input or electromotive force |

dynamical system behaviors, which are duality of second-order systems, self-excitation, orbital equivalence or structural stability, bifurcation, perturbation, harmonic balance, transient behaviors, frequency-amplitude and phase-amplitude relationships, jump phenomenon or singularity occurrence, frequency entrainment or synchronization, and so on. In particular, the self-induced current (voltage) or electricity generation appears if applying to the Liènard system.

Comparison Between Electrical and Mechanical Systems

Referred to [3, Page 341], the comparison between mechanical and electrical systems as the table (1):
the damping coefficient c in a mechanical system is analogous to R in an electrical system such that the resistance R, in common, could be as a energy dissipative device. There exists a series problem caused by the analogy between the mechanical and electrical systems. As a result, the damping term has to be a specific bandwidth of frequency response and just behaved an absorbent property as the previous definitions. The resistance has neither to be the frequency response nor absorbing but just had the balance or circle feature only. This is a crucial misunderstanding for two analogous systems.

Dielectric Materials

Referring to [31, Chapter 4, 5, 8, 9], [20, Part One], [21, Chapter 1], [8, Chapter 14], the response of a material to an electric field can be used to advantage even when no charge is transferred. These effects are described by the dielectric properties of the material. Dielectric materials posses a large energy gap between the valence and conduction bands; thus the materials a high electrical resistivity. Because dielectric materials are used in the AC circuits, the dipoles must be able to switch directions, often in the high frequencies, where the dipoles are atoms or groups of atoms that have an unbalanced charge. Alignment of dipoles causes polarization which determines the behavior of the dielectric material. Electronic and ionic polarization occur easily even at the high frequencies. Some energy is lost as heat when a dielectric material polarized in the AC electric field. The fraction of the energy lost during each reversal is the dielectric loss. The energy losses are due to current leakage and dipoles friction (or change the direction). Losses due to the current leakage are low if the electrical resistivity is high, typically which behaves 10¹¹ Ohm·m or more. Dipole friction occurs when reorientation of the dipoles is difficult, as in complex organic molecules. The greatest loss occurs at frequencies where the dipoles almost, but not quite, can be reoriented. At lower frequencies, losses are low because the dipoles have time to move. At higher frequencies, losses are low because the dipoles do not move at all.

For a capacitor made from dielectric ceramics, referred to [20, Part One], [21, Chapter 1], [31, Page 253-255], its capacitance C, which is equivalent to one ideal capacitor Cᵢ and series resistance Rₛ in the FIG. 5, is function of frequency ω, equivalent series resistance Rₛ and loss tangent of dielectric materials tan (δ) as

$$C = \frac{tan ( δ )}{{R}_{s} ω} \qquad ( 1 )$$

respectively. That is, if changing the Rₛ, tan(δ) for different materials or ω, the C becomes a variable capacitance.

### Cauchy-Riemann Theorem

Referring to the [42], [12], [40] and [4], the complex variable analysis is a fundamental mathematical tool for the electrical circuit theory. In general, the impedance function consists of the real and imaginary parts. For each part of impedance functions, they are satisfied the Cauchy-Riemann Theorem. Let a complex function be

z(x, y)=F(x, y)+iG(x, y) (2)

where F(x, y) and G(x, y) are analytic functions in a domain D and the Cauchy-Riemann theorem is the first-order derivative of functions F(x, y) and G(x, y) with respect to x and y becomes

$$\begin{matrix}\frac{\partial F}{\partial x} = \frac{\partial G}{\partial y} & ( 3 ) \\ and & \\ \frac{\partial F}{\partial y} = - \frac{\partial G}{\partial x} & ( 4 )\end{matrix}$$

Furthermore, taking the second-order derivative with respect to x and y,

$$\begin{matrix}\frac{{\partial }^{2} F}{\partial {x}^{2}} + \frac{{\partial }^{2} F}{\partial {y}^{2}} = 0 & ( 5 ) \\ and & \\ \frac{{\partial }^{2} G}{\partial {x}^{2}} + \frac{{\partial }^{2} G}{\partial {y}^{2}} = 0 & ( 6 )\end{matrix}$$

also F(x, y) and G(x, y) are called the harmonic functions.

From the equation (2), the total derivative of the complex function z(x, y) is

$$d z ( x , y ) = ( \frac{\partial F}{\partial x} d x + \frac{\partial F}{\partial y} d y ) + i ( \frac{\partial G}{\partial x} d x + \frac{\partial G}{\partial y} d y ) \qquad ( 7 )$$

and substituting equations (3) and (4) into the form of (7), then the total derivative of the complex function (2) is dependent on the real function F(x, y) or in terms of the real-valued function F(x, y) (real part) only,

$$d z ( x , y ) = ( \frac{\partial F}{\partial x} d x + \frac{\partial F}{\partial y} d y ) + i ( \frac{\partial F}{\partial x} d y - \frac{\partial F}{\partial y} d x ) \qquad ( 8 )$$

and in terms of a real-valued function G(x, y) (imaginary part) only,

$$dz ( x , y ) = ( \frac{\partial G}{\partial y} dx - \frac{\partial G}{\partial x} dy ) + i ( \frac{\partial G}{\partial x} dx + \frac{\partial G}{\partial y} dy ) \qquad ( 9 )$$

There are the more crucial facts behind the (8) and (9) potentially. As a result, the total derivative of the complex function (7) depends on the real (imaginary) part of (2) function F(x, y) or G(x, y) only and never be a constant value function. One said, if changing the function of real part, the imaginary part function is also varied and determined by the real part via the equations (3) and (4). Since the functions F(x, y) and G(x, y) have to satisfy the equations (5) and (6), they are harmonic functions and then produce the frequency related elements discussed at the analytic continuation section. Moreover, the functions of real and imaginary parts are not entirely independent referred to the Hilbert transforms in the textbooks [18, Page 296] and [20, Page 5 and Appendix One].

Analytic Continuation

The impedance of the circuit has been discussed in this section. According to the equation (11) has shown that a PDR and NDR coupled in series in a circuit can induce significant, enlarged harmonic, sub-harmonic, super-harmonic and interharmonic components which will modulate all together to present multi-band waveforms with broad bandwidth.

For each analytic function F(z) in the domain D, the Laurent series expansion of F(z) is defined as the following

$$\begin{matrix}F ( z ) = {\sum }_{n = - ∞}^{∞} {{a}_{n} ( z - {z}_{0} )}^{n} \\ = … + {{a}_{- 2} ( z - {z}_{0} )}^{- 2} + {{a}_{- 1} ( z - {z}_{0} )}^{- 1} + {a}_{0} + …\end{matrix} \qquad ( 10 )$$

where the expansion center z₀ is arbitrarily selected. Since this domain D for this analytic function F(z), any regular point imparts a center of a Laurent series [42, Page 223], i.e.,

$$F ( z ) = {\sum }_{- ∞}^{∞} {{c}_{n} ( z - {z}_{j} )}^{n}$$

where zⱼ is an arbitrary regular point in this complex analytic domain D for j=0, 1, 2, 3, . . . For each index j, the complex variable is the product of its norm and phase,

$$z - {z}_{j} = \vert z - {z}_{j} \vert {e}^{i {θ}_{j}} \\ and \\ F ( z ) = {\sum }_{- ∞}^{∞} {c}_{n} {\vert ( z - {z}_{j} ) \vert}^{n} {e}^{i n {ω}_{j} t} \qquad ( 11 )$$

As long as a loop is formed the impedance function can be written in the form as the equation above. For each phase angle θⱼ, the corresponding frequency elements are naturally produced, say harmonic frequency ωⱼ. For different zⱼ correspond to the impedances with different values, frequencies and phases. Now we have the following results:
1. As the current passing through any smoothing conductor (without singularities), the frequencies are induced in nature.
2. This conductor imparts an order-∞ resonant coupler.
3. This conductor is to be as an antenna without any bandwidth limitation.
4. Dynamic impedance matched.

0.1 Positive and Negative Differential Resistors (PDR, NDR)

More inventively, due to observing the positive and negative differential resistors properties qualitatively, we introduce the Cauchy-Riemann equations, [27, Part 1,2], [42], [12], [40] and [4], for describing a system impedance transient behaviors and particularly in some sophisticated characteristics system parametrization by one dedicated parameter ω. Consider the impedance z in specific variables (i, v) complex form of

z=F(i, v)+jG(i, v) (12)

where i, v are current and voltage respectively. Assumed that the functions F(i, v) and G(i, v) are analytic in the specific domain. From the Cauchy-Riemann equations (3) and (4) becomes as following

$$\begin{matrix}\frac{\partial F}{\partial i} = \frac{\partial G}{\partial v} \\ and & ( 13 ) \\ \frac{\partial F}{\partial v} = \frac{\partial G}{\partial i} & ( 14 )\end{matrix}$$

where in these two functions there exists one relationship based on the Hilbert transforms [18, Page 296] and [20, Page 5]. In other words, the functions F(i, v) and G(i, v) do not be obtained individually. Using the chain rule, equations (13) and (14) are further obtained

$$\begin{matrix}\frac{\partial F}{\partial ω} \frac{d ω}{d i} = \frac{\partial G}{\partial ω} \frac{d ω}{d v} \\ and & ( 15 ) \\ \frac{\partial F}{\partial ω} \frac{d ω}{d v} = - \frac{\partial G}{\partial ω} \frac{d ω}{d i} & ( 16 )\end{matrix}$$

where the parameter ω could be the temperature field T, magnetic field flux intensity B, optical field intensity I, in the electric field for examples, voltage v, current i, frequency f or electrical power P, in the mechanical field for instance, magnitude of force F, and so on. Let the terms

$$\begin{matrix}\{ \begin{matrix}\frac{d ω}{d v} > 0 \\ \frac{d ω}{d i} > 0\end{matrix} \\ or & ( 17 ) \\ \{ \begin{matrix}\frac{d ω}{d v} < 0 \\ \frac{d ω}{d i} < 0\end{matrix} & ( 18 )\end{matrix}$$

be non-zero and the same sign. Under the same sign conditions as equation (17) or (18), from equation (15) to equation (16),

$$\begin{matrix}\frac{\partial F}{\partial ω} > 0 \\ and & ( 19 ) \\ \frac{\partial F}{\partial ω} < 0 & ( 20 )\end{matrix}$$

should be held simultaneously. From the viewpoint of making a power source, the simple way to perform equations (17) and (18) is to use the pulse-width modulation (PWM) method. The further meaning of equations (17) and (18) is that using the variable frequency ω in pulse-width modulation to current and voltage is the most straightforward way, i.e.,

$$\{ \begin{matrix}\frac{d ω}{d v} \neq 0 \\ \frac{d ω}{d i} \neq 0\end{matrix}$$

After obtaining the qualitative behavoirs of equation (19) and equation (20), also we need to further respectively define the quantative behavoirs of equation (19) and equation (20). Intuitively, any complete system described by the equation (12) could be analogy to the simple-parallel oscillator as FIG. 1 or simple-series oscillator as FIG. 2 which corresponds to 2^{nd}-order differential equation respectively either as (23) or (26). Referring to [41, Vol 2, Chapter 8,9,10,11,22,23], [17, Page 173], [6, Page 181], [22, Chapter 10] and [14, Page 951-968], as the FIG. 1, let the current iₗ and voltage v_{C} be replaced by x, y respectively. From the Kirchhoff's Law, this simple oscillator is expressed as the form of

$$\begin{matrix}L \frac{d x}{d t} = y & ( 21 ) \\ C \frac{d y}{d t} = - x + {F}_{p} ( y ) & ( 22 )\end{matrix}$$

or in matrix form

$$[ \begin{matrix}\frac{d x}{d t} \\ \frac{d y}{d t}\end{matrix} ] = [ \begin{matrix}0 & \frac{1}{L} \\ - \frac{1}{C} & 0\end{matrix} ] [ \begin{matrix}x \\ y\end{matrix} ] + [ \begin{matrix}0 \\ \frac{{F}_{p} ( y )}{C}\end{matrix} ] \qquad ( 23 )$$

where the function Fₚ(y) represents the generalized Ohm's law and for the single variable case, Fₚ(x) is the real part function of the impedance function equation (12), the “p” in short, is a “parallel” oscillator. Furthermore, equation (23) is a Liènard system. If taking the linear from of Fₚ(y),

Fₚ(y)=Ky

and K>0, it is a normally linear Ohm's law. Also, the states equation of a simple series oscillator in the FIG. 2 is

$$\begin{matrix}L \frac{d x}{d t} = y - {F}_{s} ( x ) & ( 24 ) \\ C \frac{d y}{d t} = - x & ( 25 )\end{matrix}$$

in the matrix form,

$$[ \begin{matrix}\frac{d x}{d t} \\ \frac{d y}{d t}\end{matrix} ] = [ \begin{matrix}0 & \frac{1}{L} \\ - \frac{1}{C} & 0\end{matrix} ] [ \begin{matrix}x \\ y\end{matrix} ] + [ \begin{matrix}- \frac{{F}_{s} ( x )}{L} \\ 0\end{matrix} ] \qquad ( 26 )$$

The i_{C}, vₗ have to be replaced by x, y respectively. The function Fₛ(x) indicates the generalized Ohm's law and (26) is the Liènard system too. Again, considering one system as the figure FIG. 2, let L,C be to one, then the system (26) becomes the form of

$$[ \begin{matrix}\frac{d x}{d t} \\ \frac{d y}{d t}\end{matrix} ] = [ \begin{matrix}y - {F}_{s} ( x ) \\ - x\end{matrix} ] \qquad ( 27 )$$

To obtain the equilibrium point of the system (26), setting the right hand side of the system (27) is zero

$$\{ \begin{matrix}y - {F}_{s} ( 0 ) = 0 \\ - x = 0\end{matrix}$$

where Fₛ (0) is a value of the generalized Ohm's law at zero. The gradient of (27) is

$$[ \begin{matrix}- {F}_{s}^{′} ( 0 ) & 1 \\ - 1 & 0\end{matrix} ]$$

Let the slope of the generalized Ohm's law Fₛ′(0) be a new function as fₛ(0)

fₛ(0)≡Fₛ′(0)

the correspondent eigenvalues λ_{1,2}^{s} are as

$${λ}_{1 , 2}^{s} = \frac{1}{2} [ - {f}_{s} ( 0 ) \pm \sqrt{{( {f}_{s} ( 0 ) )}^{2} - 4} ]$$

Similarly, in the simple parallel oscillator (23),

fₚ(0)≡Fₚ′(0)

the equilibrium point of (23) is set to (Fₚ(0), 0) and the gradient of (23) is

$$[ \begin{matrix}0 & 1 \\ - 1 & {f}_{p} ( 0 )\end{matrix} ]$$

the correspondent eigenvalues λ_{1,2}^{p} are

$${λ}_{1 , 2}^{p} = \frac{1}{2} ( {f}_{p} \pm \sqrt{{( {f}_{p} ( 0 ) )}^{2} - 4} )$$

The qualitative properties of the systems (23) and (26), referred to [14] and [22], are as the following:
1. fₛ(0)>0, or fₚ(0)<0, its correspondent equilibrium point is a sink.
2. fₛ(0)<0, or fₚ(0)>0, its correspondent equilibrium point is a source.

Thus, observing previous sink and source quite different definitions, if the slope value of impedance function Fₛ(x) or Fₚ(y), fₛ(x) or fₚ(y) is a positive value

Fₛ′(x)=fₛ(x)>0 (28)

or

Fₚ′(y)=fₚ(y)>0 (29)

it is the name of the positive differential resistivity or PDR. On contrary, it is a negative differential resistivity or NDR.

Fₛ′(x)=fₛ(x)<0 (30)

or

Fₚ′(y)=fₚ(y)<0 (31)
3. if fₛ(0)=0 or fₚ(0)=0 its correspondent equilibrium point is a bifurcation point, referred to [23, Page 433], [24, Page 26] and [22, Chapter 10] or fixed point, [2, Chapter 1, 3, 5, 6], or singularity point, [7], [1, Chapter 22, 23, 24].

Fₛ′(x)=fₛ(x)=0 (32)

or

Fₚ′(y)=fₚ(y)=0 (33)

Liènard Stabilized Systems

This section has used periodical motion to check a system's stability, and also has explained the role of PDR and NDR in a stable dynamical system. Taking the system equation (23) or equation (26) is treated as a nonlinear dynamical system analysis, we can extend these systems to be a classical result on the uniqueness of the limit cycle, referred to [1, Chapter 22, 23, 24], [24, Page 402-407], [33, Page 253-260], [22, Chapter 10,11] and many articles [26], [19], [30], [28], [29], [16], [11], [39], [10], [15], [9], [13] for a dynamical system as the form of

$$\{ \begin{matrix}\frac{d x}{d t} = y - F ( x ) \\ \frac{d y}{d t} = - g ( x )\end{matrix} \qquad ( 34 )$$

under certain conditions on the functions F and g or its equivalent form of a nonlinear dynamics

$$\frac{{d}^{2} x}{d {t}^{2}} + f ( x ) \frac{d x}{d t} + g ( x ) = 0 \qquad ( 35 )$$

where the damping function f(x) is the first derivative of impedance function F(x) with respect to the state x

f(x)=F′(x) (36)

Based on the spectral decomposition theorem [23, Chapter 7], the damping function has to be a non-zero value if it is a stable system. The impedance function is a somehow specific pattern like as the FIG. 3,

y=F(x) (37)

From equation (34), equation (35) and equation (36), the impedance function F(x) is the integral of damping function f(x) over one specific operated domanin x>0 as

F(x)=∫₀^{x}f(s)ds (38)

Under the assumptions that F, g ∈ C¹(R), F and g are odd functions of x, F(0)=0, F′(0)<0, F has single positive zero at x=a, and F increases monotonically to infinity for x≧a as x→∞, it follows that the Liènard's system equation (34) has exactly one limit cycle and it is stable. Comparing the (38) to the bifurcation point defined in the section (0.1), the initial condition of the (38) is extended to an arbitrary setting as

F(x)=∫ₐ^{x}f(ζ)dζ (39)

where a Å R. Also, the FIG. 4 is modified as where the dashed lines are different initial conditions. Based on above proof and carefully observing the function (36) in the FIG. 4, we conclude the critical insights of the system (34). We conclude that an adaptive-dynamic damping function F(x) with the following properties:
1. The damping function is not a constant. At the interval,

α≦a
the impedance function F(x) is

F(x)<0
The function derivative of F(x) should be

F′(x)=f(x)≧0 (40)
which is a PDR as defined by (28) or (29) and

F′(x)=f(x)<0 (41)
which is a NDR as defined by (30) or (31), and both hold simultaneously. Which means that the impedance function F(x) has the negative and positive slopes at the interval α≦a.
2. Following the Liènard theorem [33, Page 253-260], [22, Chapter 10,11], [24, Chapter 8] and the correspondent theorems, corollaries and lemma, we can further conclude that one stabilized system which has at least one limit cycle, all solutions of the system (34) converge to this limit cycle even asymptotically stable periodic closed orbit. In fact, this kind of system construction can be realized a stabilized system in Poincaré sense [33, Page 253-260], [22, Chapter 10, 11], [17, Chapter 1,2,3,4], [6, Chapter 3].

Furthermore, one nonlinear dynamic system is as the following form of

$$\begin{matrix}\frac{{d}^{2} x}{d {t}^{2}} + ɛ f ( x , y ) \frac{d x}{d t} + g ( x ) = 0 \\ or & ( 42 ) \\ \{ \begin{matrix}\frac{d x}{d t} = y - ɛ F ( x ) \\ \frac{d y}{d t} = - g ( x )\end{matrix} \\ where & ( 43 ) \\ f ( x , y ) & ( 44 )\end{matrix}$$

is a nonzero and nonlinear damping function,

g(x) (45)

is a nonlinear spring function, and

F(x, y) (46)

is a nonlinear impedance function also they are differentiable. If the following conditions are valid
1. there exists a>0 such that f(x, y)>0 when \sqrt{x²+y²}≦a.
2. f(0, 0)<0 (hence f(x, y)<0 in a neighborhood of the origin).
3. g(0)=0, g(x)>0 when x>0, and g(x)<0 when x<0.
4. G(x)=∫₀^{x}g(u)du→∞ as x→∞. then (42) or (43) has at least one periodic solution.

Frequency-Shift Damping Effect

This section has used frequency shifting to re-define power generation and dissipation. This section also has revealed frequency shifting produced by a PDR and NDR coupled in series. Referring to the books [4, p 313], [35, Page 10-11], [25, Page 13] and [40, page 171-174], we assume that the function is a trigonometric Fouries series generated by a function g(t) ∈ L(I), where g(t) should be bounded and the unbounded case in the book [40, page 171-174] has proved, and L(I) denotes Lebesgue-integrable on the interval I, then for each real β, we have

$${lim}_{ω \to ∞} {\int }_{I}^{ } g ( t ) {e}^{i ( ω t + β )} d t = 0 \qquad ( 47 )$$

where

e^{i(ωt+β)}=cos(ωt+β)+i sin(ωt+β)

the imaginary part of (47)

$${lim}_{ω \to ∞} {\int }_{I}^{ } g ( t ) sin ( ω t + β ) d t = 0 \qquad ( 48 )$$

and real part of (47)

$${lim}_{ω \to ∞} {\int }_{I}^{ } g ( t ) cos ( ω t + β ) d t = 0 \qquad ( 49 )$$

are approached to zero as taking the limit operation to infinity, ω→∞, where equation (48) or (49) is called “Riemann-Lebesgue lemma” and the parameter ω is a positive real number. If g(t) is a bounded constant and ω>0, it is naturally the (48) can be further derived into

$$\vert {\int }_{a}^{b} {e}^{i ( ω t + β )} d t \vert = \vert \frac{{e}^{i a ω} - {e}^{i b ω}}{ω} \vert \leq \frac{2}{ω}$$

where [a, b] ∈ I is the boundary condition and the result also holds if on the open interval (a, b). For an arbitrary positive real number E>0, there exists a unit step function s(t), referred to [4, p 264], such that

$${\int }_{I}^{ } \vert g ( t ) - s ( t ) \vert d t < \frac{ɛ}{2}$$

Now there is a positive real number M such that if ω≧M,

$$\vert {\int }_{I}^{ } s ( t ) {e}^{i ( ω t + β )} d t \vert < \frac{ɛ}{2} \qquad ( 50 )$$

holds. Therefore, we have

$$\begin{matrix}\vert {\int }_{I}^{ } g ( t ) {e}^{i ( ω t + β )} d t \vert \leq \vert {\int }_{I}^{ } ( g ( t ) - s ( t ) ) {e}^{i ( ω t + β )} d t \vert + \\ \vert {\int }_{I}^{ } s ( t ) {e}^{i ( ω t + β )} d t \vert \\ \leq {\int }_{I}^{ } \vert g ( t ) - s ( t ) \vert d t + \frac{ɛ}{2} \\ < \frac{ɛ}{2} + \frac{ɛ}{2} = ɛ\end{matrix} \qquad ( 51 )$$

i.e., (48) or (49) is verified and hold.

According to the Riemann-Lebesgue lemma, the equation (47) or (49) and (48), as the frequency ω approaches to ∞ which means

ω>>0

then

$${lim}_{ω \to ∞} {\int }_{I}^{ } g ( t ) {e}^{i ( ω t + β )} d t = 0 \qquad ( 52 )$$

The equation (52) is a foundation of the energy dissipation. For removing any destructive energy component, (52) tells us the truth whatever the frequencies are produced by the harmonic and subharmonic waveforms and completely “damped” out by the ultra-high frequency modulation.

Observing (52), the function g(t) is an amplitude of power which is the amplitude-frequency dependent and seen the book [24, Chapter 3,4,5,6]. It means if the higher frequency ω produced, the more g (t) is attenuated. When moving the more higher frequency, the energy of (52) is the more rapidly diminished. We conclude that a large part of the power has been dissipated to the excited frequency ω fast drifting across the board of each reasonable resonant point, rather than transferred into the thermal energy (heat). After all applying the energy to a system periodically causes the ω to be drifted continuously from low to very high frequencies for the energy absorbing and dissipating. Again removing the energy, the frequency rapidly returns to the nominal state. It is a fast recovery feature. That is, this system can be performed and quickly returned to the initial states periodically.

As the previous described, realized that the behavior of the frequency getting high as increasing the amplitude of energy and vice versa, expressed as the form of

ω=ω(g(t)) (53)

The amplitude-frequency relationship as (53) which induces the adaptation of system. It means which magnitude of the energy produces the corresponding frequency excitation like as a complex damper function (44).

Consider one typical example, assumed that given the voltage

v(t)=V₀e^{j(ω}^{ᵥ}^{t+α}^{ᵥ}⁾ (54)

and current

i(t)=I₀e^{j(ω}^{ᵢ}^{t+α}^{ᵢ}⁾ (55)

the total applied power is defined as

$$\begin{matrix}P = {\int }_{0}^{T} i ( t ) v ( t ) d t & ( 56 ) \\ = \frac{{V}_{0} {I}_{0}}{( {ω}_{v} + {ω}_{i} )} ( {e}^{j ( {α}_{v} + {α}_{i} + \frac{π}{2} )} ( 1 - {e}^{j ( {ω}_{v} + {ω}_{i} ) T} ) ) & ( 57 )\end{matrix}$$

Let the frequency ω and phase angle β be as

ω=ωᵥ+ωᵢ

and

β=αᵢ+αᵥ

then equation (57) becomes into the complex form of

$$\begin{matrix}P = π ( ω , β , T ) + j Q ( ω , β , T ) & ( 58 ) \\ = \frac{{V}_{0} {I}_{0}}{ω} ( {e}^{j ( β + \frac{π}{2} )} ( 1 - {e}^{j ω T} ) ) & ( 59 )\end{matrix}$$

where real power π (ω, β, T) is

$$π ( ω , β , T ) = \frac{2 {V}_{0} {I}_{0} sin ( ω T ) cos ( 2 π - 2 β - ω T )}{ω} \qquad ( 60 )$$

and virtual power Q (ω, β, T) is

$$Q ( ω , β , T ) = \frac{2 {V}_{0} {I}_{0} sin ( ω T ) sin ( 2 π - 2 β - ω T )}{ω} \qquad ( 61 )$$

respectively. Observing (47), taking limit operation to (58), (57) or (59),

$${lim}_{ω \to ∞} \frac{{V}_{0} {I}_{0}}{ω} ( {e}^{j ( β + \frac{π}{2} )} ( 1 - {e}^{j ω T} ) ) = 0 \qquad ( 62 )$$

the electric power P is able to filter out completely no matter how they are real power (60) or virtual power (61) via performing frequency-shift or Doppler's shift operation, where ωᵥ, ωᵢ are frequencies of the voltage v(t) and current i(t), and αᵥ, αᵢ are correspondent phase angles and T is operating period respectively. Let the real power to be zero,

$$2 π - 2 β - ω T = \frac{π}{2}$$

which means that the frequency ω is shifted to

$${ω}_{Vir} = \frac{1}{T} ( \frac{3 π}{2} - 2 β )$$

The total power (58) is converted to the maximized virtual power

$$Max ( Q ( {ω}_{Vir} , β , T ) ) = \frac{2 {V}_{0} {I}_{0} sin ( {ω}_{Vir} T )}{{ω}_{Vir}} \\ = \frac{2 {V}_{0} {I}_{0} T cos ( 2 β )}{( \frac{3 π}{2} - 2 β )}$$

### Similarly,

$$2 π - 2 β - ω T = 0$$

$$or$$

$${ω}_{Re} = \frac{2}{T} ( π - β )$$

the total power (58) is totally converted to the maximized real power

$$Max ( π ( {ω}_{Re} , β , T ) ) = \frac{2 {V}_{0} {I}_{0} sin ( {ω}_{Re} T )}{{ω}_{Re}} \\ = \frac{{V}_{0} {I}_{0} T sin ( 2 β )}{( β - π )}$$

In fact, moving out the frequency element ω as the (62) is power conversion between real power (60) and virtual power (61).

Maximized Power Transfer Theorem

Consider the voltage source Vₛ to be

Vₛ=V₀

and its correspondent impedance Zₛ

Zₛ=Rₛ+jQₛ

The impedance of the system load Z_{L} is

Z_{L}=R_{L}+jQ_{L}

The maximized power transmission occurrence if R_{L} and Q_{L} are varied, not to be the constants,

R_{L}=Rₛ (63)

where the resistor Rₛ is called equivalent series resistance or ESR and

Q_{L}=−Qₛ (64)

Comparing (63) to (64), the impedances of voltage source and the system load should be conjugated, i.e.,

Z_{L}=Zₛ*

then the overall impedance becomes the sum of Zₛ+Z_{L}, or

$$Z = {Z}_{s} + {Z}_{L} \\ = {R}_{s} + {R}_{L} + j ( {Q}_{s} + {Q}_{L} ) \qquad ( 65 )$$

The power of impedance consumption is

$$P = {I}^{2} {R}_{L} \\ = {( \frac{[ ( {R}_{s} + {R}_{L} ) - j ( {Q}_{s} + {Q}_{L} ) ]}{{( {R}_{s} + {R}_{L} )}^{2} + {( {Q}_{s} + {Q}_{L} )}^{2}} )}^{2} {V}_{0}^{2} {R}_{L}$$

Let the imaginary part of P be setting to zero,

(Qₛ+Q_{L})=0 (66)

i.e.,

Qₛ=−Q_{L}

or resonance mode. In fact, it is an impedance matched motion. The power of the total impedance consumption becomes just real part only,

$$P = \frac{{V}_{0}^{2} {R}_{L}}{{( {R}_{s} + {R}_{L} )}^{2}}$$

From the basic algebra,

$$\frac{{R}_{s} + {R}_{L}}{2} \geq \sqrt{{R}_{s} {R}_{L}}$$

where Rₛ and R_{L} have to be the positive values,

Rₛ, R_{L}≧0 (67)

or

(Rₛ−R_{L})²=0

In other words, the resistance Rₛ and R_{L} are the same magnitudes as

Rₛ=R_{L} (68)

The power of impedance consumption P becomes an averaged power Pₐᵥ

$${P}_{av} = \frac{1}{2} \frac{{V}_{0}^{2}}{{R}_{L}} \\ = \frac{{V}_{0}^{2}}{( 2 {R}_{L} )} \qquad ( 69 )$$

and the total impedance becomes twice of the resistance R_{L} or Rₛ.

Z=2R_{L} (70)

Let (64) be a zero, i.e., impedance matched,

Qₛ=Q_{L}=0 (71)

from (68), the total impedance and consumed power P are (70), (69) respectively. In other word, comparing the (2) to (71), it is hard to implement that the imaginary part of impedance (65) keeps zero. But applying the (3) and (4) operations into the form of (7), the results have been verified on the Cauchy-Riemann theorem, also it is a possible way to create the zero value of imaginary part of total impedance (65) or (7). Another way is producing a conjugated part of (65) or (7) dynamically and adaptively or order-∞ resonance mode.

Tunnel Diode

In 1958, Leo Esaki, a Japanese scientist, discovered that a semi-conductor junction diode is heavily doped with impurities, it will have a region of negative differential resistance. This heavy doping produces an extremely narrow depletion zone. And because of the heavy doping, a tunnel diode exhibits an unusual current-voltage characteristic curve as compared with that of an ordinary junction diode. FIG. 6 has shown a characteristic curve of a typical tunnel diode. The three most important aspects of this characteristic curve are: (1) the forward current increase to a peak indicated by I_{P} with a small applied forward bias, (2) the decreasing forward current with an increasing forward bias to a minimum valley current indicated by I_{V}, and (3) the normal increasing forward current with further increases in the bias voltage. The portion of the curve between I_{P} and I_{V} is the region of negative resistance. The curve of tunnel diode can also be viewed having PDR and NDR properties at the same time. FIG. 7b has shown the structure of a typical tunnel diode in which a heavily doped p-n junction 703 is formed between a p-type 701 and a n-type 702 semiconductors or devices. The p-n junction 703 of the tunnel diode can also be called tunneling junction in the present invention.

### REFERENCES

[1] Nicholas Minorsky. Nonlinear oscillations. Van Nostrand, New York., http://www.alibris.com, 1962.
[2] Alberto Abbondandolo. Morse Theory for Hamiltonian Systems. CRC Press., http://www.crcpress.com/, 2000.
[3] D. K. Anand. An Introduction to Control Systems. Pergamon Press., http://www.amazon.com/, 1974.
[4] Tom M. Apostol. Mathematical Analysis. Addison-Wesley Publishing Company., http://www.aw-bc.com/, 2nd edition, 1975.
[5] V. I. Arnold. Ordinary Differential Equations. MIT Press., http://www.mitpress.com/, 1973.
[6] V. I. Arnold. Geometrical Methods in the Theory of Ordinary Differential Equations. Springer-Verlag., http://www.springer-ny.com/, 2nd edition, 1988.
[7] V. I. Arnold. Theory of Singularities and its Applicatoins., volume 1. American Mathematical Society., http://www.ams.org/, 2nd edition, 1990.
[8] Donald R. Askeland. The Science and Engineering of Materials. PWS Publishers., alternate edition, 1985.
[9] J. Balakrishnan. A geometric framework for phase synchronization in coupled noisy nonlinear systems. Physical Review E, 73:036206, 2006.
[10] Timoteo Carletti and Gabriele Villari. A note on existence and uniqueness of limit cycles for lienard systems, 2003.
[11] V. K. Chandrasekar, M. Senthilvelan, and M. Lakshmanan. An unusual lienard type nonlinear oscillator with properties of a linear harmonic oscillator, 2004.
[12] E. T. Copson. An introduction to the theory of functions of a complex variable. Oxford University Press., http://www.amazon.com/, 4th edition, 1948.
[13] M. C. Cross, A. Zumdieck, Ron Lifshitz, and J. L. Rogers. Synchronization by nonlinear frequency pulling. Physical Review Letters, 93:224101, 2004.
[14] R. Wong F. Cuker. The Collected Papers of Stephen Smale., volume 3. Singapore University Press., http://www.worldscibooks.com/mathematics, 2000.
[15] H. Giacomini and S. Neukirch. On the number of limit cycles of the lienard equation, 1997.
[16] Jaume Gine and Maite Grau. A note on “relaxation oscillators with exact limit cycles”, 2005.
[17] John Guckenheimer and Philip Holmes. Nonlinear Oscillations, Dynamical Systems, and Bifurcations of Vector Fields. Springer-Verlag., http://www.springer-ny.com/, 1997.
[18] Ernest A. Guillemin, editor. Synthesis of Passive Networks: Theory and Methods Appropriate to the Realization and Approximation Problems. John Wiley and Sons., 1957.
[19] Edward H. Hellen and Matthew J. Lanctot. Nonlinear damping of the lc circuit using anti-parallel diodes, 2006.
[20] Arthur R. Von Hippel. Dielectrics and Waves. A John Wiley and Sun, Inc., http://www.wiley.com, 1954.
[21] Arthur Von Hippel. Dielectric Materials and Applications. Artech House Publishers., http://www.artechhouse.com, 1995.
[22] Morris W. Hirsh and Stephen Smale. Differential Equations, Dynamical Systems and Linear Algebra. Academic Press., http://www.academicpress.com/, 1974.
[23] Thomas J. R. Hughes. Jerrold E. Marsden. Mathematical Foundations of Elasticity. Prentice-Hall, Inc., http://www.doverpublications.com/, 1984.
[24] D. W. Jordan and Peter Smith. Nonlinear Ordinary Differential Equations. Oxford University Press., http://www.oup.co.uk/academic/, 3rd edition, 1999.
[25] Yitzhak Katznelson. An Introduction to Harmonic Analysis. Cambridge University Press, http://www.amazon.com/, 2nd edition, 1968.
[26] Alexandra S. Landsman and Ira B. Schwartz. Predictions of ultra-harmonic oscillations in coupled arrays of limit cycle oscillators, 2006.
[27] Serge Lang. Complex Analysis. Springer-Verlag., http://www.springer.de/phy/books/ssp, 4th edition, 1999.
[28] Jose-Luis Lopez and Ricardo Lopez-Ruiz. The limit cycles of lienard equations in the strongly non-linear regime, 2002.
[29] Jose-Luis Lopez and Ricardo Lopez-Ruiz. Approximating the amplitude and form of limit cycles in the weakly non-linear regime of lienard systems, 2006.
[30] Jose-Luis Lopez and Ricardo Lopez-Ruiz. The limit cycles of lienard equations in the weakly nonlinear regime, 2006.
[31] A. J. Moulson and J. M. Herbert. Electrocramics: Materials, Properties, Applications. Wiley and Sun Ltd., http://www3.wileye.com, 2nd edition, 2003.
[32] Peter J. Olver. Applications of Lie Groups to Differential Equations. Springer-Verlag., http://www.springer-ny.com/, 1993.
[33] Lawrence Perko. Differential Equations and Dynamical Systems. Springer-Verlag, New York, Inc., http://www.springer-ny.com, 3rd edition, 2000.
[34] Jerrold E. Marsden. Ralph Abraham. Foundations of Mechanics. Perseus Publishing., http://www.perseusbooksgroup.com/front.html, 2nd edition, 1984.
[35] Michael Reed and Barry Simon. Methods of Modern Mathematical Physics: Fourier Analysis, Self-Adjointness., volume 2. Academic Press., http://www.academicpress.com, 1975.
[36] Michael Reed and Barry Simon. Methods of Modern Mathematical Physics: Analysis of Operators., volume 4. Academic Press., http://www.academicpress.com, 1978.
[37] Michael Reed and Barry Simon. Methods of Modern Mathematical Physics: Scattering Theory., volume 3. Academic Press., http://www.academicpress.com, 1979.
[38] George F. Simmons. Introduction to Topology and Modern Analysis. McGRAW-HILL Inc., http://books.mcgraw-hill.com, 1963.
[39] Ali Taghavi. On periodic solutions of lienard equations, 2004.
[40] E. T. Whittaker and G. N. Watson. A Course of Modern Analysis. Cambridge Mathematical Library., http://www.cambridge.org, 4th edition, 1927.
[41] Matthew Sands. WRichard P. Feynman, Robert B. Leighton. Feynman Lectures On Physics: The Complete And Definitive Issue., volume 3. Addison Wesley Publishing Company., http://www.aw-bc.com, 2nd edition, 1964.
[42] A. David Wunsch. Complex Variables with Applications. Addison-Wesley Publishing Company Inc., http://www.aw-bc.com/, 1983.

### SUMMARY OF THE INVENTION

It is the first objective of the present invention to provide a field tunnel device to generate tunneling effect for outputing self-excited multi-band waveforms and the field tunnel device is field-interacted.

It is the second objective of the present invention to provide the field tunnel device as a power conversion device to drive a high speed loading such as p-n junction device.

It is the third objective of the present invention to provide an inventive structure of the field tunnel device and a coupled p-n junction device.

It is the fourth objective of the present invention to provide a high-frequency operated capacitor with largely variable capacitance.

It is the fifth objective of the present invention to provide the field tunnel device as a power conversion device to control the switch of a power module more precisely.

### BRIEF DESCRIPTION OF THE DRAWINGS

FIG. 1 has shown a parallel oscillator;

FIG. 2 has shown a serial oscillator;

FIG. 3 has shown the function F(x) and a trajectory F of Liènard system;

FIG. 4 has shown the impedance function F(x) is independent of the initial condition setting;

FIG. 5 a capacitor C decomposed into an ideal capacitor Cᵢ, a series parasitic resistor Rₛ;

FIG. 6 has shown a characteristic curve of a typical tunnel diode;

FIG. 7a has shown a typical tunnel diode in which a tunneling junction is formed between a p-type and a n-type devices;

FIG. 7b has shown an embodiment of a field tunnel device;

FIG. 7c has shown another embodiment of a field tunnel device;

FIG. 7d has shown a field tunnel device by coupling a NDR with a typical tunnel diode;

FIG. 7e has shown a plurality of PDRs and NDRs coupled with a field tunnel device to compensate the device's waveforms;

FIG. 8a has shown a field tunnel device coupled with a p-n junction device;

FIG. 8b has shown a circuit loop contains a power source and the device of FIG. 8a; and

FIG. 8c is obtained by adding terminals to FIG. 8a in which a first terminal couples with the first device and a second terminal couples with the third device.

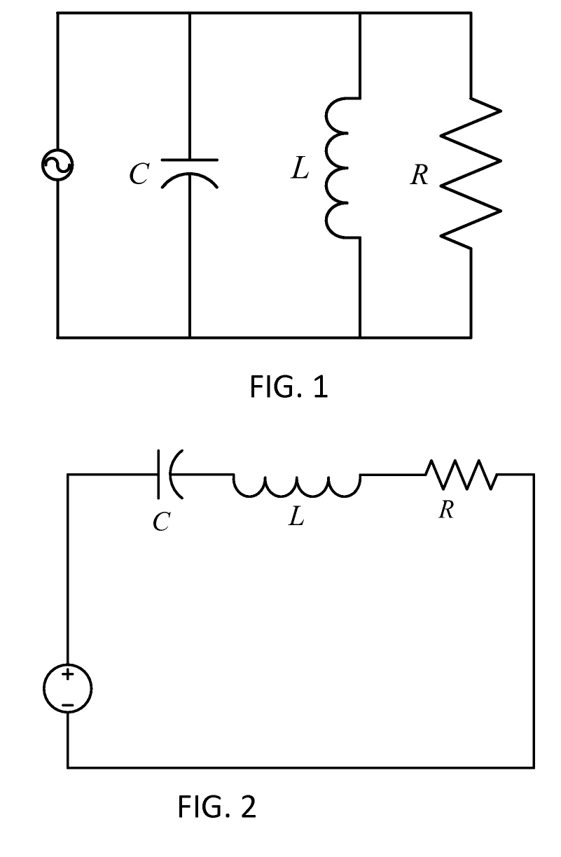

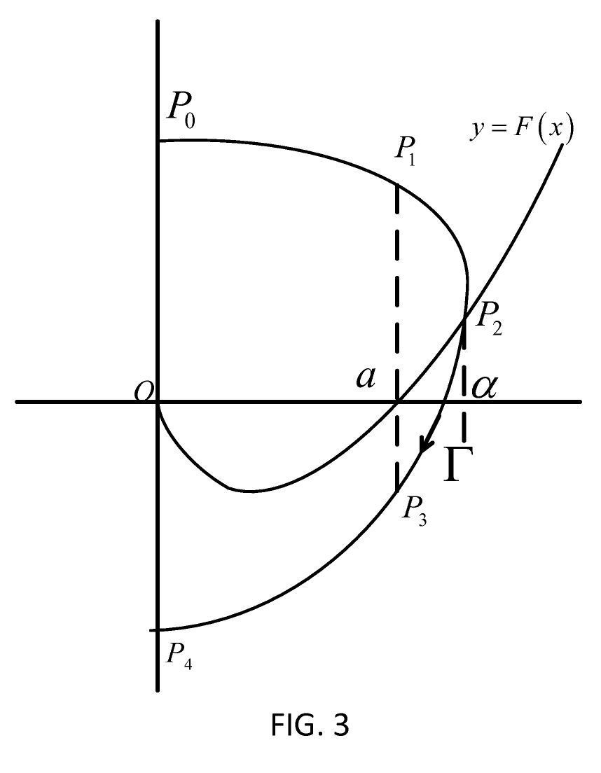

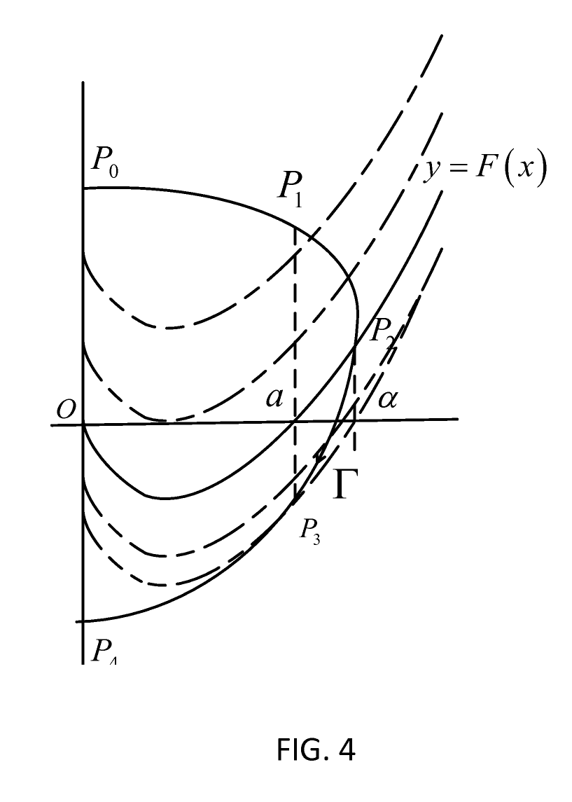

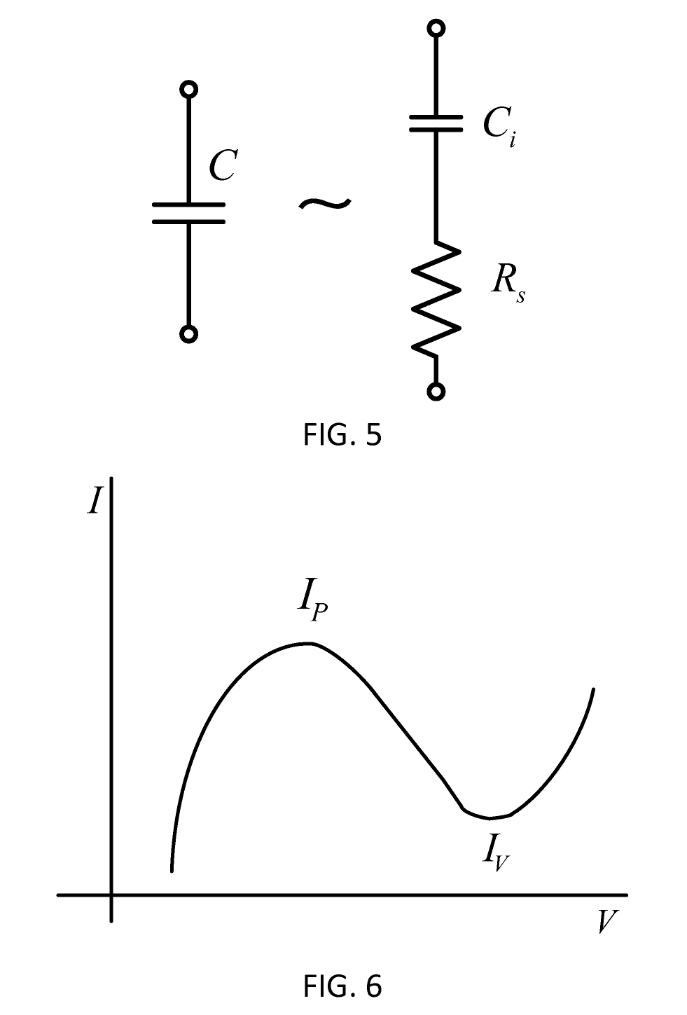

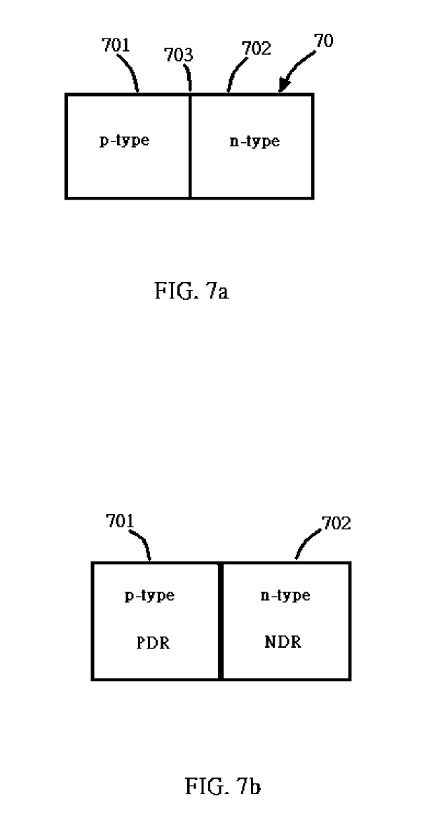

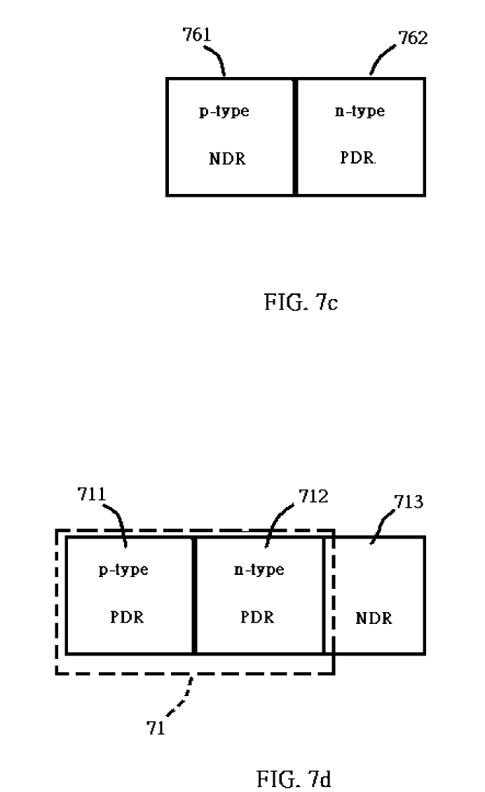

### DETAILED DESCRIPTION OF THE INVENTION

According to the equations (13) in the background section, the resistance variations can be generated by fields interactions. And, according to the equations (15) and (16), the positive differential resistor or PDR in short defined by the equation (19) or (29) and the negative differential resistor or NDR in short defined by the equation (20) or (31) can be generated by fields interactions in which the field can be temperature field T, magnetic field such as magnetic flux intensity B, optical field such as optical field intensity I, electric field such as voltage v, current i, frequency f or electrical power P, acoustic field, or mechanical field such as magnitude of force F, and so on, or, any combinations of them listed above. The PDR and NDR in the present invention are not limited to be produced by any particular field.

The impedance of the circuit has been analyzed in the analytic continuation section of the background information. For any close loop the impedance function can be written in the form as equation (10) and the following three parts (19), (20) and (32) or (33) respectively are always held true, which means that the properties of the PDR and NDR are the nature or intrinsic properties in any closed loop. By adding resistance-frequency-responding devices such as PDR and NDR can reflect, realize and stand out the nature properties, increase the frequency responses of the loop and let the circuit more observable. Any circuit without resistance-frequency-responding device its dynamic behavior will be more suppressed and concealed, and, the circuit's static behavior will be more emphasized than its dynamical behavior. A PDR and NDR coupled in series in a circuit can induce significant, more observable and enlarged harmonic, sub-harmonic, super-harmonic and interharmonic components which will modulate all together to generate significant multiband waveforms with considerably broad bandwidth.

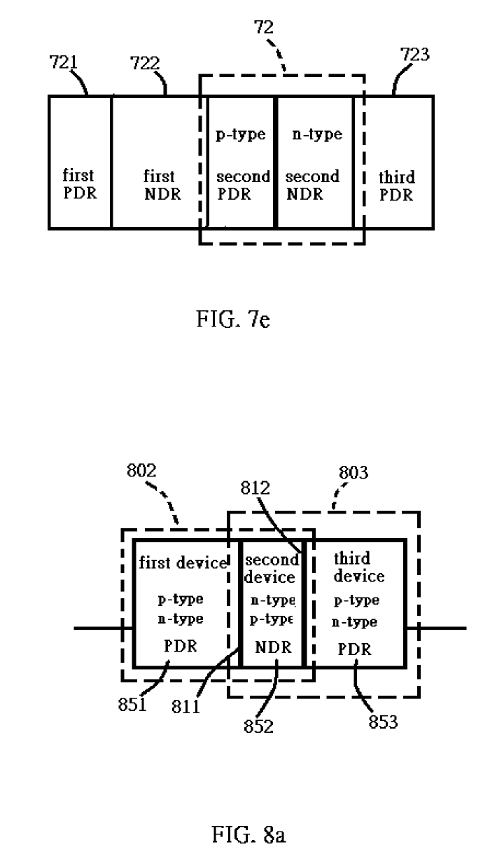

It has been known to us that the tunnel diode can be simply expressed by coupling a p-type device with a n-type device and a heavily doped p-n junction is formed between them. The p-n junction of the tunnel diode can also be called as tunneling junction or tunneling-junction device in the present invention. Each of the p-type device, n-type device and tunneling-junction device can be classified as either a PDR or NDR. The tunnel diode can generate tunneling effect and, further, any device can generate tunnel effect can be called tunnel device in the present invention. FIG. 7a has simply shown a tunnel diode 70 in which a p-type device 701, a n-type device 702 and a tunneling-junction device 703 are seen. A field tunnel device can be obtained by introducing the concept of the PDR and NDR into the tunnel diode. A field tunnel device is defined that any device can generate tunneling effect comprising a PDR and a NDR coupled in series, and, the PDR or PDRs and NDR or NDRs are produced by fields interactions which include thermal field, optical field, electric field, magnetic field, pressure field, acoustic field, or any combination of them. When the tunneling effect is triggered it provides a baseband which will modulate together with the frequency responses of the field-interacted PDR and NDR to violently generate more frequency elements to produce self-excited multi-band waveforms whose bandwidth are a lot broader than that of a typical tunnel diode. By selecting the PDR and NDR with proper differential slopes, the frequency responses of the field tunnel device will be in the form of the multi-band waveforms with considerably broad bandwidth. Further, the fields interactions applied on the field tunnel device will generate the variations of PDR and NDR resulting in the variations of the tunnel diode's resistance which can change the voltage levels for the tunneling happening resulting in increasing the chances for generating the tunneling.

FIG. 7b to FIG. 7e have shown a couple of the field tunnel devices based on the structure of the tunnel diode.

An embodiment of a field tunnel device, among the p-type device, n-type device and the tunneling-junction device of the tunnel diode comprise a PDR and a NDR coupled in series. An embodiment of a field tunnel device of FIG. 7b has shown that a p-type device 701 of a tunnel diode is a PDR and a n-type device 702 of the tunnel diode is a NDR. Another embodiment of a field tunnel device of FIG. 7c has shown that a p-type device 761 of a tunnel diode is a NDR and a n-type device 762 of the tunnel diode is a PDR. FIG. 7d has shown a field tunnel device that a NDR 773 serially couples with a typical tunnel diode 77 in which both of a p-type device 771 and a n-type device 772 are PDRS. The advantage of the embodiment of FIG. 7d is that the existed and mature technology of the tunnel diode in which both the p-type and n-type devices are PDRs can be employed in constructing the field tunnel device.

A plurality of the PDRs and/or NDRs with different differential slopes coupled in series with the field tunnel device can help to compensate the device's waveforms if their frequency responses can significantly modulate together. An embodiment shown in FIG. 7e, a first PDR 721, a first NDR 722 and a third PDR 723 couple in series with a field tunnel device 72 to compensate the device's waveforms if their frequency responses can significantly modulate together within an effectively coupling distance, for example, an embodiment, within a single wavelength.

A power source applied to the field tunnel device will trigger the tunneling effect and produce multi-band waveforms. The power source can be a power supply, a battery, or any device which can generate power such as a p-n junction device. The term “p-n junction device” has been well known to the skilled in the art, it comprises a p-type and a n-type devices located next to each other and a p-n junction or p-n-junction device is formed between them. Please note that the p-n junction device and the p-n-junction device are different notations, in which the p-n-junction device means the p-n junction in the present invention.

P-n junction device is the main part of many semiconductor devices. P-n junction device can be classified into driving and driven p-n junction devices in the present invention.

The driving p-n junction device can convert outside field into electrical power including solarcell, optical sensor, Hall device, thermal device, pressure sensor and acoustic sensor, etc. Those driving p-n junction devices listed above can respectively convert an incident light, magnetic field, thermal field, pressure field and acoustic field into electrical power. Those driving p-n junction devices can trigger the field tunnel device's tunneling effect and output self-excited multi-band waveforms if the converted power can overcome the distance between the p-n junction device and the field tunnel device. One of the main objective of the present invention is that those driving p-n junction devices can be used to drive the field tunnel device to output self-excited multi-band waveforms, which is not DC any more.

The field tunnel device is also good for driving high frequency loading such as p-n junction device which is called the driven p-n junction device. This driven p-n junction device includes LED, memory, CPU or the gate of the power module, etc. The gate of the power module is for receiving the control of the power module and it can be viewed having p-n junction device. If the multi-band waveforms produced by the field tunnel device can cover the frequency responses of the loading there are more chances to get impedance matchings into resonance mode which will bring the most performance and consume the least energy. The field tunnel device with quite broad bandwidth is a necessity. The frequency responses of the tunnel diode can be x-band or higher so that that of the field tunnel device can be the same level.

The reactance property of a p-n junction device can be more emphasized than its resistance property driven by the high speed field tunnel device so that the driven p-n junction device is more like a capacitor with variable capacitance. The equation (1) talking about the capacitance found in the background section can be used to explain this. This equation explicitly reveals that the capacitance is in term of frequency and resistance. For p-n junction device, each frequency is corresponding to the capacitance of each parasitic capacitor in the p-n junction device, and, each specific frequency will be delivered to its corresponding parasitic capacitor for charging and discharging. By the frequencies matchings make AC pass those parasitic capacitors possible and the charges in the parasitic capacitor surely can be cancelled, which means that those parasitic capacitors look like not existed for AC condition, which further means that the known Miller effect can be fixed. The present invention can also solve the known EMI problem. For p-n junction device, EMI problem is induced by the parasitic capacitor coupled with inductances which can be easily from conductive wires. With the solution to the parasitic capacitor in the p-n junction device the EMI problem can be significantly reduced.

The equation (1) also shows that the capacitance of the parasitic capacitor is also in term of resistance. Different resistances are corresponding to different capacitances of the parasitic capacitors too. The PDR and NDR contribute the variations of the resistance which correspond to different capacitances. A p-n junction device driven by the field tunnel device can be used as a capacitor with variable or controllable capacitance and its Miller effect and EMI problem can also be significantly cancelled.

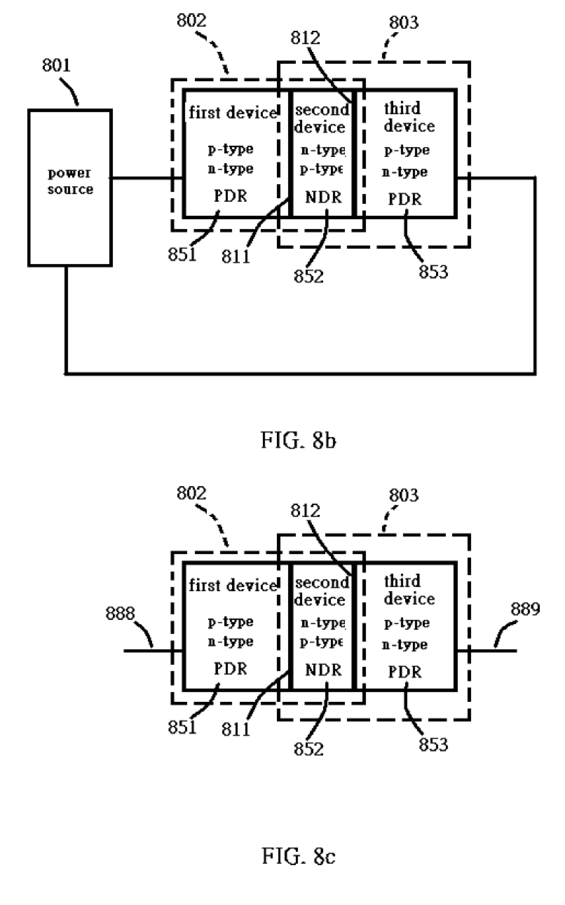

FIG. 8a has shown an inventive structure of the field tunnel device with a coupled a p-n junction device, in which the p-n junction device can be a driving p-n junction device or a driven p-n junction device. FIG. 8a has shown that a first device 851 couples with a second device 852 which couples with a third device 853, in which the first 851 and second 852 devices construct a first p-n junction device 802 having a first p-n junction 811 or called a first p-n-junction device 811, and, the second device 852 and the third device 853 construct a second p-n junction device 803 having a second p-n junction 812 or called a second p-n-junction device 812. Please note again that the p-n junction device and p-n-junction device are different notations. The first device 851, the second device 852 and the third device 853 are either respectively as p-n-p type or n-p-n type as a typical transistor.

Either the first 802 or second 803 p-n junction device is the tunnel diode which can generate tunneling effect and among the first device 851, second device 852, third device 853, first p-n-junction device 811 and second p-n-junction device 812 comprise a PDR and a NDR coupled in series. The first 802 or second 803 p-n junction device not chosen as the tunnel diode can be either as the driving or driven p-n junction device depending on its role.

Two embodiments, the first device 851, the second device 852 and the third device 853 can respectively be PDR, NDR and PDR, or NDR, PDR and NDR. The first 802 or second 803 p-n junction device not chosen as the tunnel diode can be a driving p-n junction device to trigger the tunnel diode's tunneling effect and produce self-excited multi-band waveforms, or, the first 802 or second 803 p-n junction device not chosen as the tunnel diode can be the driven p-n junction device as a loading.

An embodiment of FIG. 8a has shown that the tunnel diode is the first p-n junction device 802 constructed by the first 851 and second 852 devices, and, the first device 851, the second device 852 and the third device 853 are respectively assigned as a PDR, NDR and PDR.

For the driven p-n junction device, the frequency responses of the tunnel diode 802 modulated with that of the PDR and NDR can be delivered to the working p-n junction 812 of the driven p-n junction device 803 so that they should be disposed within a significantly coupling distance, for example, an embodiment, within a single wavelength, which is possible in the nowadays semiconductor technology. And, further, the frequency responses of the tunnel diode 802 modulated with that of the PDR and NDR can cover that of the driven p-n junction device 803 to gain more chances to get impedance matchings into resonance mode. Again, the driven p-n junction device can be a LED, a memory cell, a capacitor with variable capacitance or the gate of a power module for receiving the control. The multi-band waveforms sent by the field tunnel device on the gate of the power module can control the switch of the power module much more precisely.

The driving p-n junction device can be a solarcell, optical sensor, Hall sensor, thermal sensor, acoustic sensor or pressure sensor. P-n junction device used in the present invention is a general term to represent those devices listed above although they respectively have different structures.

FIG. 8b has shown a loop formed by including a power source 801 and the device of FIG. 8a. The power source 801 can be a DC or an AC running at a certain base frequency which can also be modulated with the frequency responses of the field tunnel device to an expected bandwidthes.

The present invention is not limited to any particular tunnel diode or any device can produce any tunneling effect. The present invention is not limited to any particular structure and design constructing a tunneling diode or tunnel device. And, the present invention is not limited to any particular p-n junction device. The present invention is not limited to any particular structure constructing a p-n junction device.

The field tunnel device and the field tunnel device with a coupled p-n junction device of FIG. 8a might need terminals for coupling outside circuit and the terminals can also be classified as a PDR or NDR, which can also be accounted as an element or elements contributing their PDR or NDR properties to those devices. Those terminals can use NDR to decrease its resistance. FIG. 8c is obtained by adding terminals to FIG. 8a in which a first terminal 888 couples with the first device 851 and a second terminal 889 couples with the third device 853. The terminals 888 and 889 can use NDR to decrease the resistance.

1. A field tunnel device for producing self-excited multi-band waveforms, comprising:
a p-type device,
a n-type device, and
a tunneling-junction device coupled with the p-type device and the n-type device,
wherein
the p-type device is a PDR, the n-type is a PDR and the tunneling-junction device is a NDR;
the p-type device is a PDR, the n-type is a NDR and the tunneling-junction device is a PDR;
the p-type device is a PDR, the n-type is a NDR and the tunneling-junction device is a NDR;
the p-type device is a NDR, the n-type is a PDR and the tunneling-junction device is a NDR;
the p-type device is a NDR, the n-type is a NDR and the tunneling-junction device is a PDR; or
the p-type device is a NDR, the n-type is a PDR and the tunneling-junction device is a PDR.

2. The field tunnel device of claim 1, wherein the PDR and NDR are generated by thermal field, optical field, electric field, magnetic field, pressure field, acoustic field, or any combination of them.

3. The field tunnel device of claim 2, wherein
the p-type device and the n-type device are PDRS; and
further comprises a NDR coupled in series with the p-type device or the n-type device for compensating the field tunnel device's waveforms.

4. An assembly, comprising:
a first device,
a second device coupled with the first device to form a first p-n junction device having a first p-n-junction device, and
a third device coupled with the second device to form a second p-n junction device having a second p-n-junction device, wherein
the first device, second device, third device, first p-n-junction device and second p-n-junction device comprises a PDR and a NDR coupled in series, and
either the first p-n junction device or the second p-n junction device is a tunnel diode.

5. The assembly of claim 4, wherein the PDR and NDR are generated by thermal field, optical field, electric field, magnetic field, pressure field, acoustic field, or any combination of them.

6. The assembly of claim 5, wherein the first or second p-n junction device not chosen as the tunnel diode is a driving p-n junction device which drives the tunnel diode for generating tunneling effect.

7. The assembly of claim 5, wherein the first or second p-n junction device not chosen as the tunnel diode is a driven p-n junction device.

8. The assembly of claim 6, wherein the driving p-n junction device is a solarcell, an optical sensor, a Hall sensor, a thermal sensor, an acoustic sensor or a pressure sensor.

9. The assembly of claim 7, wherein the driven p-n junction device is a LED, a memory cell, the gate of a power module for receiving the switching control or a capacitor with variable capacitance.

10. The assembly of claim 8, wherein the first device, the second device and the third device are respectively as a p-type, n-type and p-type devices and respectively as a PDR, NDR and PDR.

11. The assembly of claim 8, wherein the first device, the second device and the third device are respectively as a p-type, n-type and p-type devices and respectively as a NDR, PDR and NDR.

12. The assembly of claim 8, wherein the first device, the second device and the third device are respectively as a p-type, n-type and p-type devices and respectively as a PDR, PDR and NDR.

13. The assembly of claim 8, wherein the first device, the second device and the third device are respectively as a n-type, p-type and n-type devices and respectively as a PDR, NDR and PDR.

14. The assembly of claim 8, wherein the first device, the second device and the third device are respectively as a n-type, p-type and n-type devices and respectively as a NDR, PDR and NDR.

15. The assembly of claim 8, wherein the first device, the second device and the third device are respectively as a n-type, p-type and n-type devices and respectively as a PDR, PDR and NDR.

16. The assembly of claim 9, wherein the first device, the second device and the third device are respectively as a p-type, n-type and p-type devices and respectively as a PDR, NDR and PDR.

17. The assembly of claim 9, wherein the first device, the second device and the third device are respectively as a p-type, n-type and p-type devices and respectively as a NDR, PDR and NDR.

18. The assembly of claim 9, wherein the first device, the second device and the third device are respectively as a p-type, n-type and p-type devices and respectively as a PDR, PDR and NDR.

19. The assembly of claim 9, wherein the first device, the second device and the third device are respectively as a n-type, p-type and n-type devices and respectively as a PDR, NDR and PDR.

20. A field tunnel device for generating tunneling effect with multi-band waveforms, comprising,
a PDR, and
a NDR coupled in series with the PDR, wherein
the PDR and the NDR are produced by the thermal field, electrical field, magnetic field, optical field, pressure field, acoustic field, or any combination of them.
